(19) United States
(12) Patent Application Publication
(10) Pub. No.: US 2011/0275206 A1
(43) Pub. Date: Nov. 10, 2011

(54) METHOD FOR FABRICATING SEMICONDUCTOR DEVICE

(76) Inventor: Masataka KUSUMI, Niigata (JP)

(21) Appl. No.: 13/102,542

(22) Filed: May 6, 2011

(30) Foreign Application Priority Data
May 10, 2010 (JP) 2010-108086

(51) Int. Cl. H01L 21/3205

(52) U.S. Cl. 438/585; 257/E21.294

(57) ABSTRACT

In a method for fabricating a semiconductor device, a first insulating film which is to serve as a gate insulating film of a protected element is formed on a semiconductor substrate. At least a portion of the first insulating film is removed in a protective element portion. Thereafter, a surface of the first insulating film is nitrided in a protected element portion. A conductive film is selectively formed, extending over the protected element portion and the protective element portion, to form a gate electrode of the protected element and an electrode of a protective element, which are connected together.

### CROSS-REFERENCE TO RELATED APPLICATION

This application claims priority to Japanese Patent Application No. 2010-108086 filed on May 10, 2010, the disclosure of which including the specification, the drawings, and the claims is hereby incorporated by reference in its entirety.

### BACKGROUND

The present disclosure relates to methods for fabricating semiconductor devices, and more particularly, to methods for fabricating semiconductor devices including a memory element and a protective element for reducing charging on a semiconductor substrate.

In semiconductor devices formed on semiconductor substrates, charging which occurs in the fabrication process has an influence on characteristics of the device, and therefore, it is important to reduce the charging to the extent possible. In particular, a semiconductor memory device in which a localized charge storage memory element made of an oxide-nitride-oxide (ONO) film and a peripheral metal-oxide-semiconductor field-effect transistor (MOSFET) are mounted on the same semiconductor substrate, is susceptible to the influence of charging occurring in the fabrication process. If charges are trapped by the ONO film due to the charging, the threshold voltage changes and fluctuates significantly, which affect a data retention characteristic. Therefore, attempts have been made to reduce the charging using a protective element. It is considerably important that not only the protective element can effectively reduce the charging, but also the protective element can be formed without reducing the performance and quality of the memory element and the peripheral MOSFET.

FIG. 20 shows a conventional charging protective element (see, for example, U.S. Pat. No. 6,337,502 B1). The gate (G) terminal of a protected element 501 is connected via a metal interconnect layer 502 to the drain (D) terminal of a protective element 503. The gate (G) terminal of the protective element 503 is connected via an interconnect 504 to a metal antenna 505. The protective element 503 is an NMOSFET. In an interconnect layer formation step, when positive charge is applied to the gate (G) terminal of the protected element 501, a positive voltage is also applied via the metal antenna 505 to the gate (G) terminal of the protective element 503. As a result, conduction occurs between the drain (D) terminal and the source (S) terminal of the protective element 503, so that charge flows into the substrate (ground) without remaining in the protected element 501. On the other hand, when negative charge is applied to the gate (G) terminal of the protected element 501, a forward bias is applied between the drain (D) and source (S) terminals and the well diffusion layer of the protective element 503, charge flows into the substrate (ground) without remaining in the protected element 501.

However, in conventional semiconductor devices, the charging can be reduced after the interconnect layer formation step, i.e., the charging cannot be reduced in the first portion of wafer processing called front-end-of-line (FEOL) processing before the interconnect layer formation step.

In FEOL processing, plasma processing is frequently used in dry etching, resist removal, ion implantation, etc., so that members formed on an insulating film are likely to be positively and negatively charged. If these members are charged, a high electric field occurs in a vertical direction of the insulating film, so that a current flows, and therefore, the insulating film is degraded. In particular, in the case of localized charge storage memory devices employing an ONO film, charge is trapped by the charge storage layer, and the trapped charge causes the initial threshold of the memory device to fluctuate. The trapped charge may be removed by a thermal treatment. However, as the size of the memory device is reduced, the temperature of the thermal treatment needs to be reduced, and therefore, it becomes more difficult to achieve the removal by the thermal treatment. As a result, there is a demand for a reduction or prevention of the charging itself.

### SUMMARY

The present disclosure describes implementations of a technique of effectively reducing or preventing the charging in semiconductor devices during FEOL processing.

An example method for fabricating a semiconductor device includes the step of forming a conductive film which is to serve as electrodes, extending over a gate insulating film of a protected element and an interface insulating film of a protective element.

Specifically, the example semiconductor device fabrication method is a method for fabricating a semiconductor device including a protected element formed in a protected element portion of a semiconductor substrate and a protective element formed in a protective element portion of the semiconductor substrate, the method including the steps of (a) forming, on the semiconductor substrate, a first insulating film which is to serve as a gate insulating film of the protected element, (b) removing at least a portion of the first insulating film in the protective element portion, (c) after step (b), nitriding or fluorinating a surface of the first insulating film in the protected element portion, and (d) after step (c), forming a conductive film extending over the protected element portion and the protective element portion to form a gate electrode of the protected element and an electrode of the protective element, the gate electrode of the protected element and the electrode of the protective element being connected together.

In the example semiconductor device fabrication method, the protected element is protected after the formation of the gate electrode of the protected element and the protective element electrode of the protective element. Therefore, the charging to the protected element can be effectively reduced or prevented even in FEOL processing.

### BRIEF DESCRIPTION OF THE DRAWINGS

FIG. 1 is a cross-sectional view showing a step in a method for fabricating a semiconductor device according to an embodiment.

FIG. 2 is a cross-sectional view showing a step in the semiconductor device fabrication method of the embodiment.

FIG. 3 is a cross-sectional view showing a step in the semiconductor device fabrication method of the embodiment.

FIG. 4 is a cross-sectional view showing a step in the semiconductor device fabrication method of the embodiment.

FIG. 5 is a cross-sectional view showing a step in the semiconductor device fabrication method of the embodiment.

FIG. 6 is a cross-sectional view showing a step in the semiconductor device fabrication method of the embodiment.

FIG. 7 is a cross-sectional view showing a step in the semiconductor device fabrication method of the embodiment.

FIG. 8 is a cross-sectional view showing a step in the semiconductor device fabrication method of the embodiment.

FIG. 9 is a cross-sectional view showing a step in the semiconductor device fabrication method of the embodiment.

FIG. 10 is a cross-sectional view showing a step in the semiconductor device fabrication method of the embodiment.

FIG. 11 is a cross-sectional view showing a step in the semiconductor device fabrication method of the embodiment.

FIG. 12 is a cross-sectional view showing a step in the semiconductor device fabrication method of the embodiment.

FIG. 13 is a cross-sectional view showing a step in the semiconductor device fabrication method of the embodiment.

FIG. 14 is a cross-sectional view showing a step in the semiconductor device fabrication method of the embodiment.

FIG. 15 is a cross-sectional view showing a step in the semiconductor device fabrication method of the embodiment.

FIG. 16 is a cross-sectional view showing a step in a variation of the semiconductor device fabrication method of the embodiment.

FIG. 17 is a cross-sectional view showing a step in the variation of the semiconductor device fabrication method of the embodiment.

FIG. 18 is a cross-sectional view showing a step in the variation of the semiconductor device fabrication method of the embodiment.

FIG. 19 is a cross-sectional view showing a step in another variation of the semiconductor device fabrication method of the embodiment.

FIG. 20 is a circuit diagram showing a conventional semiconductor device.

### DETAILED DESCRIPTION

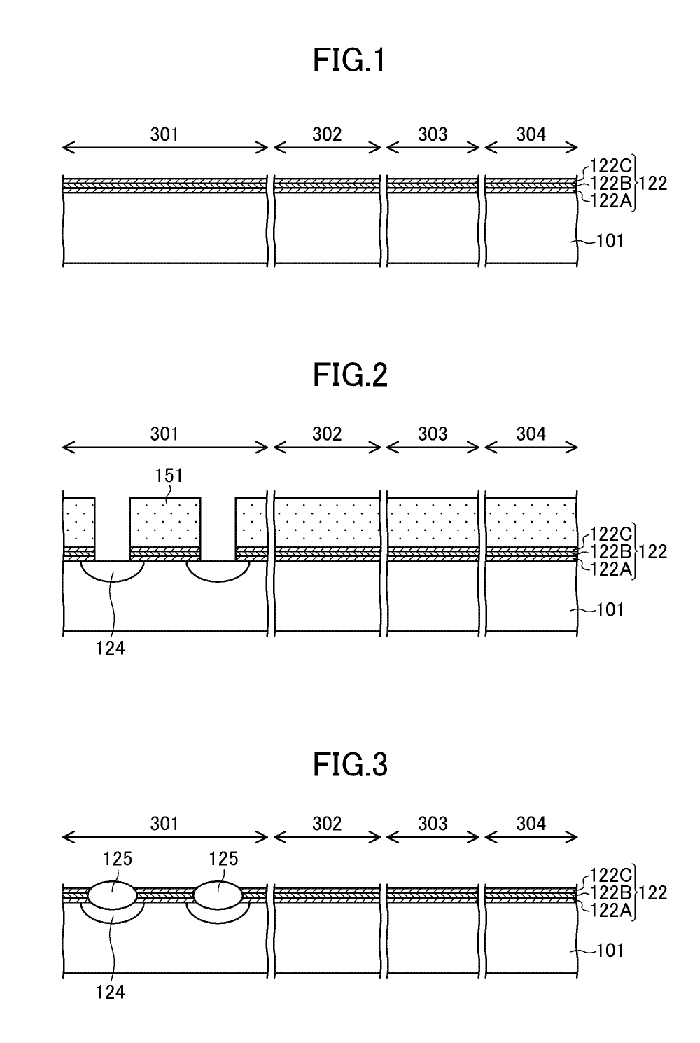

FIGS. 1-15 show a method for fabricating a semiconductor device according to an embodiment in the order in which the semiconductor device is fabricated. Each figure shows a protected element portion 301 where a memory element which is a protected element is to be formed, a protective element portion 302 where a protective diode which is a protective element is to be formed, a first peripheral element portion 303 where a low voltage transistor for a peripheral circuit is to be formed, and a second peripheral element portion 304 where a high voltage transistor for a peripheral circuit is to be formed.

(1) Formation of Memory Element

Initially, as shown in FIG. 1, an ONO film 122 which is to serve as a gate insulating film of a protected element is formed on an entire surface of a semiconductor substrate 101. For example, the ONO film 122 may be formed by forming a first silicon oxide film 122A having a thickness of about 5 nm on the semiconductor substrate 101 by thermal oxidation and then forming a first silicon nitride film 122B having a thickness of about 15 nm on the first silicon oxide film 122A by chemical vapor deposition (CVD). Next, a second silicon oxide film 122C having a thickness of about 20 nm may be formed on the first silicon nitride film 122B by thermal oxidation. Note that the second silicon oxide film 122C may have a multilayer structure including a silicon oxide film formed by thermal oxidation and a silicon oxide film formed by CVD.

Next, as shown in FIG. 2, bit line diffusion layers 124 are formed in the protected element portion 301. Specifically, a first mask pattern 151 having openings in regions where the bit line diffusion layer 124 is to be formed is formed by photolithography. The ONO film 122 is selectively removed by dry etching using the first mask pattern 151. Thereafter, arsenic (As) ions are implanted into the semiconductor substrate 101 at an acceleration voltage of 30 keV and at a dose of 2.0×10¹⁵/cm² to form the bit line diffusion layer 124.

Next, as shown in FIG. 3, the first mask pattern 151 is removed, and thereafter, an upper surface of the bit line diffusion layer 124 is oxidized by thermal oxidation, to form a bit line insulating film 125 having a thickness of about 50 nm.

(2) Formation of PN Junction

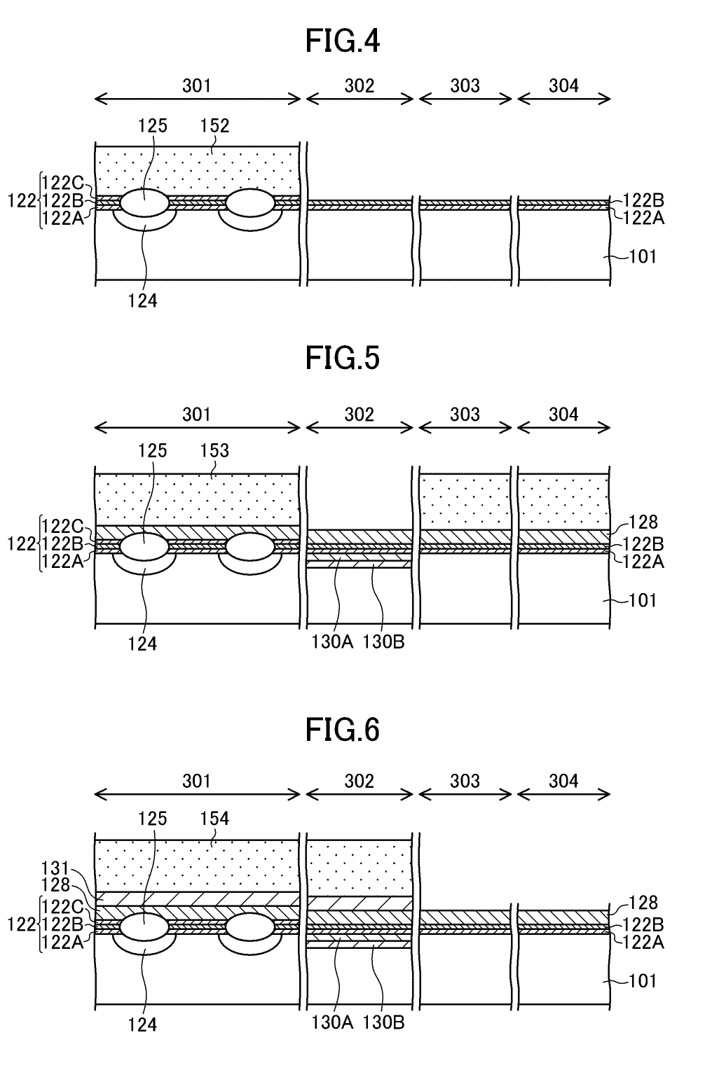

As shown in FIG. 4, a second mask pattern 152 which covers the protected element portion 301 is formed by photolithography, and thereafter, the second silicon oxide film 122C is removed in the protective element portion 302, the first peripheral element portion 303, and the second peripheral element portion 304. An ON film made of the first silicon oxide film 122A and the first silicon nitride film 122B remains in the protective element portion 302, the first peripheral element portion 303, and the second peripheral element portion 304.

Next, as shown in FIG. 5, the second mask pattern 152 is removed, and thereafter, on an entire surface of the semiconductor substrate 101, a second silicon nitride film 128 having a thickness of about 15 nm is deposited by CVD, and then a third mask pattern 153 having an opening where the protective element portion 302 is exposed is formed by photolithography. Next, a PN junction which is to serve as a protective diode is formed in the protective element portion 302. For example, arsenic (As) ions are implanted into the protective element portion 302 at an acceleration voltage of 70 keV and at a dose of 2.0×10¹⁵/cm² to form an N-type impurity diffusion layer 130A. Next, boron (B) ions are implanted into the protective element portion 302 at an acceleration voltage of 40 keV and at a dose of 1.0×10¹³/cm² to form a P-type impurity diffusion layer 130B below the N-type impurity diffusion layer 130A.

(3) Formation of Gate Insulating Film for High Voltage MOSFET

As shown in FIG. 6, the third mask pattern 153 is removed, and thereafter, a third silicon oxide film 131 is deposited in the protected element portion 301 and the protective element portion 302. For example, initially, a silicon oxide film having a thickness of about 30 nm may be deposited on an entire surface of the semiconductor substrate 101 by CVD. Thereafter, a fourth mask pattern 154 having an opening where the first peripheral element portion 303 and the second peripheral element portion 304 are exposed may be formed by photolithography. The silicon oxide film may be removed in the first peripheral element portion 303 and the second peripheral element portion 304 by wet etching using the fourth mask pattern 154.

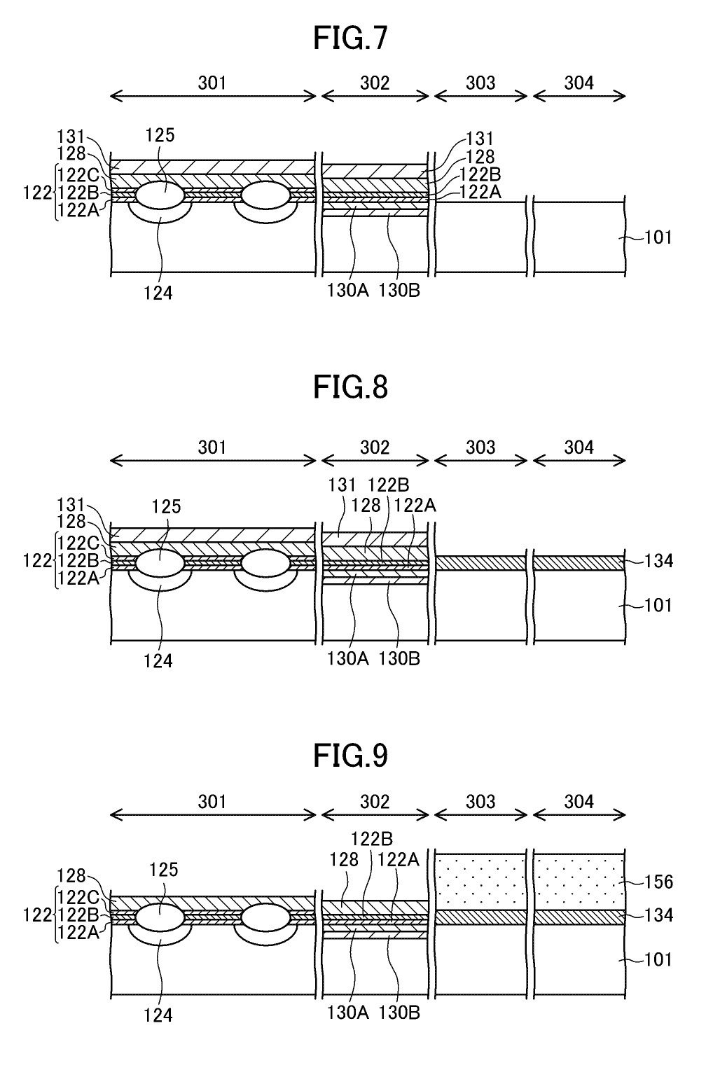

Next, as shown in FIG. 7, the fourth mask pattern 154 is removed, and thereafter, the second silicon nitride film 128 and the first silicon nitride film 122B are removed in the first peripheral element portion 303 and the second peripheral element portion 304 with hot phosphoric acid using the third silicon oxide film 131 as a mask. Next, the first silicon oxide film 122A is removed in the first peripheral element portion 303 and the second peripheral element portion 304 by wet etching. Because the third silicon oxide film 131 is thicker than the first silicon oxide film 122A, the third silicon oxide film 131 remains in the protected element portion 301 and the protective element portion 302.

Next, as shown in FIG. 8, a gate insulating film 134 having a thickness of about 5-20 nm for a high voltage MOSFET is formed in the first peripheral element portion 303 and the second peripheral element portion 304. Note that the gate insulating film 134 may have a multilayer structure which is obtained by forming a silicon oxide film by CVD and then forming a thermal oxidation film on the semiconductor substrate 101 below the silicon oxide film by thermal oxidation. Alternatively, the gate insulating film 134 may have a multilayer structure which is obtained by forming a thermal oxidation film and then forming a silicon oxide film on the thermal oxidation film by CVD.

Next, as shown in FIG. 9, a sixth mask pattern 156 having an opening where the protected element portion 301 and the protective element portion 302 are exposed is formed by photolithography, and thereafter, the third silicon oxide film 131 is removed by wet etching.

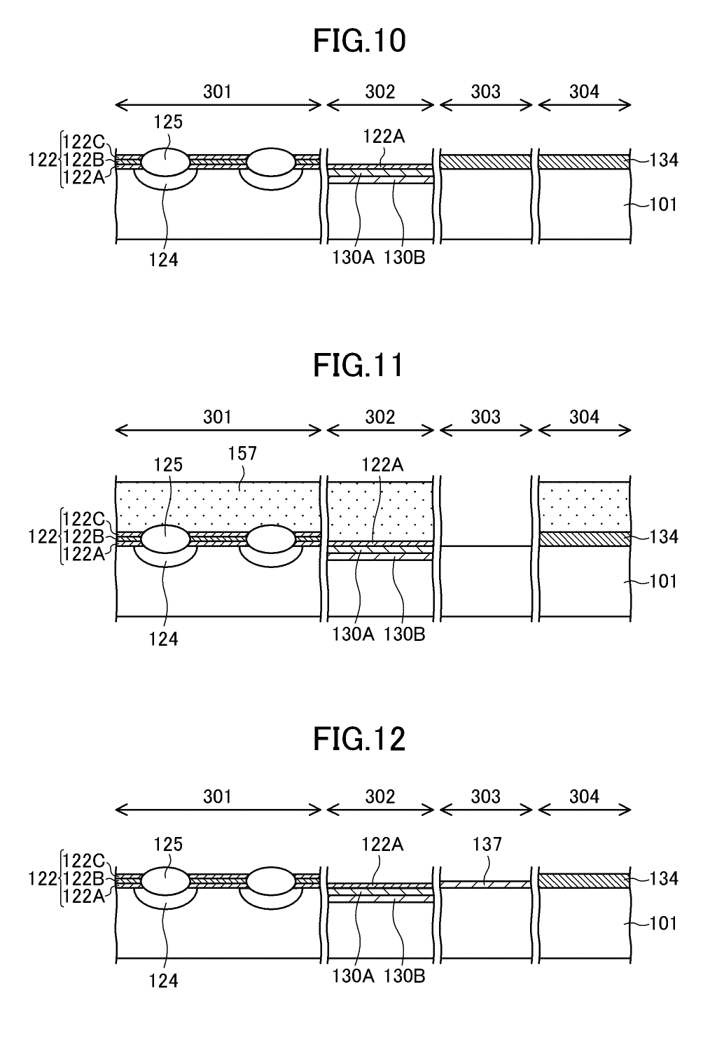

Next, as shown in FIG. 10, the sixth mask pattern 156 is removed, and thereafter, the second silicon nitride film 128 and the first silicon nitride film 122B are removed in the protected element portion 301 and the protective element portion 302 with hot phosphoric acid using the gate insulating film 134 of the high voltage MOSFET as a mask. As a result, the first silicon oxide film 122A is exposed in the protective element portion 302.

(4) Formation of Gate Insulating Film for Low Voltage MOSFET

As shown in FIG. 11, a seventh mask pattern 157 having an opening where the first peripheral element portion 303 is exposed is formed by photolithography, and thereafter, the gate insulating film 134 is removed in the first peripheral element portion 303 by wet etching.

Next, as shown in FIG. 12, the seventh mask pattern 157 is removed, and thereafter, a gate insulating film 137 having a thickness of 2-5 nm for a low voltage MOSFET is formed by thermal oxidation. Note that the thermal oxidation may be performed by furnace oxidation or rapid thermal oxidation (RTO) (external combustion oxidation) or in-situ steam generation (ISSG) oxidation (internal combustion oxidation).

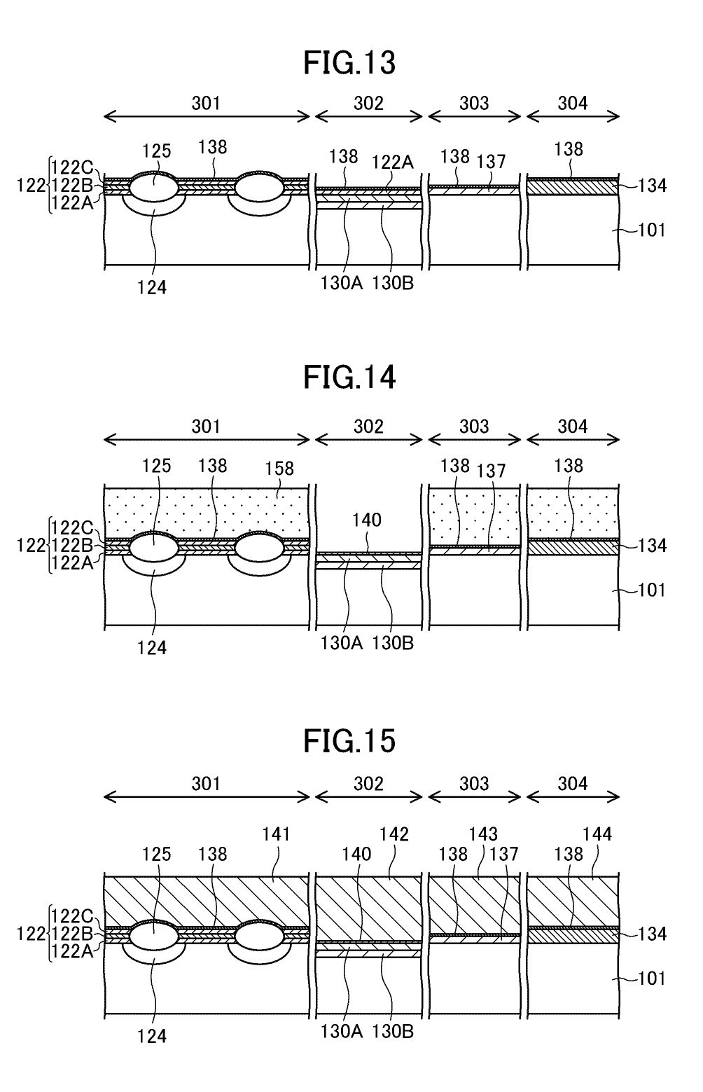

Next, as shown in FIG. 13, a nitride layer 138 which is to server as an interface layer is formed. Specifically, upper portions of the second silicon oxide film 122C formed in the protected element portion 301, the first silicon oxide film 122A formed in the protective element portion 302, the gate insulating film 137 formed in the first peripheral element portion 303, and the gate insulating film 134 formed in the second peripheral element portion 304 are plasma-nitrided. After the nitridation, annealing is performed by rapid thermal processing (RTP). By the nitridation, the film quality of the gate insulating film 137 of the low voltage MOSFET can be improved. It is also possible to reduce or prevent diffusion of boron (B) ions into the semiconductor substrate 101 when the B ions are implanted into the gate electrode. Note that the nitride layer 138 may be formed using a furnace. A fluoride layer may be formed, instead of the nitride layer, by fluoridation using fluorine instead of nitrogen.

(5) Formation of Electrode

As shown in FIG. 14, an eighth mask pattern 158 having an opening where the protective element portion 302 is exposed is formed by photolithography, and the nitride layer 138 and the first silicon oxide film 122A are removed in the protective element portion 302 by wet etching. At the end of the wet etching, ozone cleaning is performed to form an interface oxide film 140 having a thickness of about 1 nm on the semiconductor substrate 101. When a polycrystal silicon film is grown in a subsequent step, the interface oxide film 140 can reduce or prevent epitaxial growth of a portion of the polycrystal silicon film, whereby a stable device characteristic can be obtained.

Next, as shown in FIG. 15, the eighth mask pattern 158 is removed, and thereafter, a polycrystal silicon film is deposited on the protected element portion 301, the protective element portion 302, the first peripheral element portion 303, and the second peripheral element portion 304 by CVD. The deposited polycrystal silicon film is selectively removed by etching to form a control gate electrode 141 of the memory element, an electrode 142 of the protective element, a gate electrode 143 of the low voltage MOSFET, and a gate electrode 144 of the high voltage MOSFET. Note that the control gate electrode 141 is continuously formed over the protected element portion 301 to connect to the electrode 142 for the protective element in the protective element portion 302.

Thereafter, although not specifically described, in the first peripheral element portion 303 and the second peripheral element portion 304, a source and a drain are formed, and in addition, a silicide layer, a metal interconnect, a protective film, a bonding pad, etc. are optionally formed.

According to the semiconductor device and the fabrication method of this embodiment, the control gate electrode 141 in the protected element portion 301 and the diode electrode 142 in the protective element portion 302 are simultaneously formed using the same polycrystal silicon film. The control gate electrode 141 and the diode electrode 142 are connected together. Therefore, the protective diode effectively functions in steps subsequent to the formation of the polycrystal silicon film to substantially reliably prevent the charging from occurring in FEOL processing. Therefore, the performance of the memory element can be improved. Also, because the protective element is highly compatible with the memory element and the peripheral circuits (i.e., MOSFETs), the performance and quality of the memory element and the peripheral MOSFETs are not likely to be degraded.

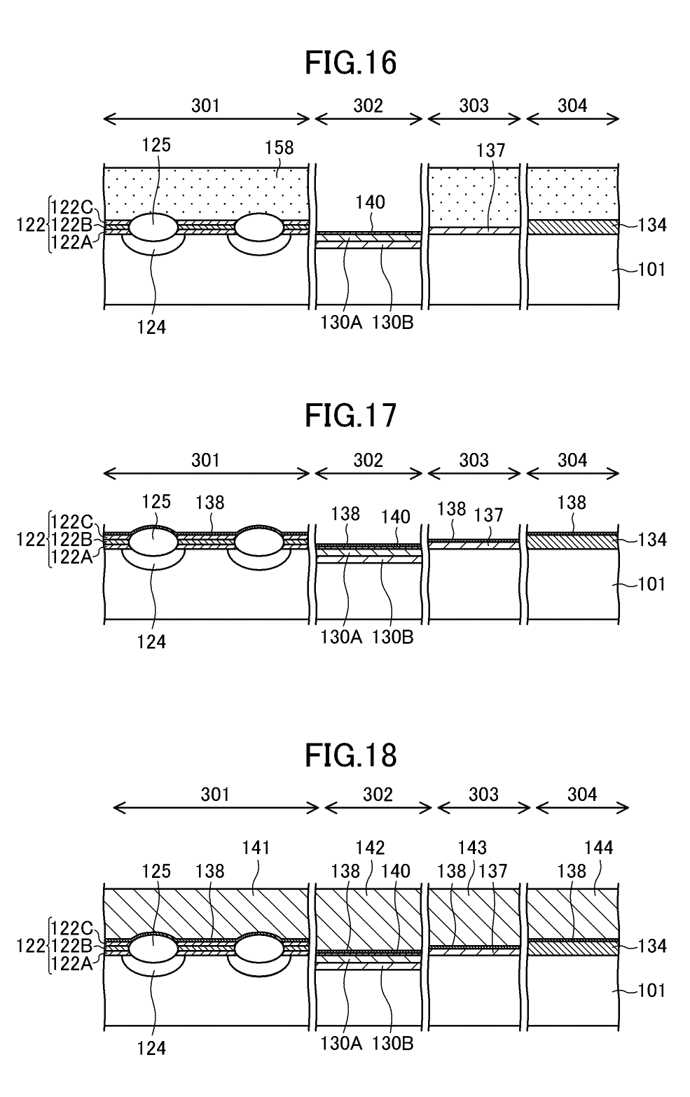

In this embodiment, after the removal of the nitride layer 138, a polycrystal silicon film is formed to form each electrode. However, the nitride layer 138 may exist between the electrode 142 of the protective element and the interface oxide film 140. In this case, as shown in FIG. 16, the gate insulating film 137 of the low voltage MOSFET may be formed, and thereafter, the first silicon oxide film 122A may be removed in the protective element portion 302 by wet etching, to form the interface oxide film 140 having a thickness of about 1 nm. Next, as shown in FIG. 17, the eighth mask pattern 158 may be removed, and thereafter, the nitride layer 138 may be formed an entire surface of the semiconductor substrate 101. Thereafter, as shown in FIG. 18, the control gate electrode 141, the electrode 142 of the protective element, the gate electrode 143 of the low voltage MOSFET, and the gate electrode 144 of the high voltage MOSFET may be formed.

The resist pattern is typically removed using ammonium hydroxide/hydrogen peroxide/water mixture (APM: NH₄OH:H₂O₂:H₂O). If the exposed surface of the gate insulating film is cleaned with APM, local pin holes are likely to occur in the gate insulating film due to the influence of the H₂O₂. The influence of the pin holes is more significant on the nitrided gate oxide film. Therefore, if the nitride layer 138 is formed after the removal of the eighth mask pattern 158, the film quality of the gate insulating film 137 of the low voltage MOSFET can be improved. Therefore, the performance and reliability of the peripheral MOSFET can be further improved.

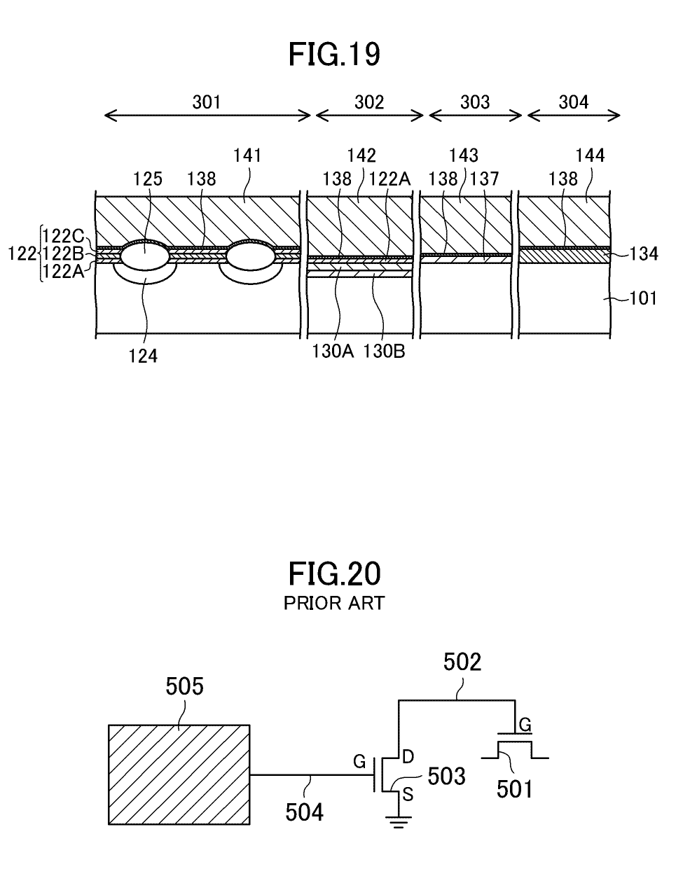

The nitride layer 138 and the first silicon oxide film 122A may exist between the electrode 142 of the protective element and the semiconductor substrate 101. In this case, in the step of FIG. 13, the nitride layer 138 is formed, and thereafter, the control gate electrode 141, the electrode 142 of the protective element, the gate electrode 143 of the low voltage MOSFET, and the gate electrode 144 of the high voltage MOSFET may be formed as shown in FIG. 19 without removing the nitride layer 138 and the first silicon oxide film 122A.

Thus, the cleaning step is not required after the nitridation following the formation of the gate insulating film 137 of the low voltage MOSFET. Therefore, the degradation of the film quality of the gate insulating film 137 of the low voltage MOSFET can be reduced or prevented. Therefore, the performance and reliability of the peripheral MOSFET can be further improved.

In this embodiment, the peripheral element portion includes two peripheral elements, i.e., the low voltage MOSFET and the high voltage MOSFET. Alternatively, the peripheral element portion may include three or more peripheral elements, or a single peripheral element.

While, in this embodiment, memory devices susceptible to the influence of the charging have been particularly described, the charging reduction effect can be similarly obtained in semiconductor devices other than memory devices.

As described, according to the semiconductor device fabrication method of the present disclosure, the charging of semiconductor devices can be effectively reduced or prevented even in FEOL processing. The present disclosure is particularly useful as methods for fabricating semiconductor devices including a memory portion including an ONO film as a gate insulating film, and a peripheral MOSFET.

What is claimed is:

1. A method for fabricating a semiconductor device including a protected element formed in a protected element portion of a semiconductor substrate and a protective element formed in a protective element portion of the semiconductor substrate, the method comprising the steps of:
(a) forming, on the semiconductor substrate, a first insulating film which is to serve as a gate insulating film of the protected element;
(b) removing at least a portion of the first insulating film in the protective element portion;
(c) after step (b), nitriding or fluorinating a surface of the first insulating film in the protected element portion; and
(d) after step (c), forming a conductive film extending over the protected element portion and the protective element portion to form a gate electrode of the protected element and an electrode of the protective element, the gate electrode of the protected element and the electrode of the protective element being connected together.

2. The method of claim 1, further comprising the step of:
(e) after step (c) and before step (d), removing a remaining portion of the first insulating film in the protective element portion to expose the semiconductor substrate, and forming an interface insulating film of the protective element on the exposed semiconductor substrate,
wherein
in step (b), a portion of the first insulating film remains, and
in step (d), the conductive film is formed on the interface insulating film in the protective element portion.

3. The method of claim 1, wherein
in step (b), a portion of the first insulating film remains,
in step (c), the surface of the first insulating film is nitrided or fluorinated in the protected element portion, and a surface of the remaining portion of the first insulating film is nitrided or fluorinated in the protective element portion, and
in step (d), the conductive film is formed on the remaining portion of the first insulating film in the protective element portion.

4. The method of claim 1, wherein
in step (b), the first insulating film is removed in the protective element portion to expose the semiconductor substrate, and an interface insulating film of the protective element is formed on the exposed semiconductor substrate,
in step (c), the surface of the first insulating film is nitrided or fluorinated in the protected element portion, and a surface of the interface insulating film is nitrided or fluorinated in the protective element portion, and
in step (d), the conductive film is formed on the interface insulating film in the protective element portion.

5. The method of claim 1, further comprising the step of:
(f) after step (a) and before step (b), forming a gate insulating film of a peripheral element in a peripheral circuit portion of the semiconductor substrate,
wherein
in step (c), the surface of the first insulating film is nitrided or fluorinated in the protected element portion, and a surface of the gate insulating film of the peripheral element is nitrided or fluorinated in the peripheral circuit portion.

6. The method of claim 1, wherein
in step (c), the surface of the first insulating film is thermally treated after the nitridation or fluorination.

7. The method of claim 1, wherein
the protected element is a memory element, and
the gate electrode is a control gate electrode of the memory element.

8. The method of claim 7, wherein
the memory element is a metal-oxide-nitride-oxide-silicon (MONOS) memory element.

9. The method of claim 1, wherein
in step (c), plasma processing is performed.
